(19) United States
(12) Patent Application Publication
(10) Pub. No.: US 2013/0334388 A1
(43) Pub. Date: Dec. 19, 2013

(54) MOUNTING APPARATUS FOR CONNECTOR ASSEMBLY

(71) Applicants: HONG FU JIN PRECISION INDUSTRY (ShenZhen) CO., LTD., (US); HON HAI PRECISION INDUSTRY CO., LTD., New Taipei (TW)

(72) Inventor: ZHAN-YANG LI, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/868,334

(22) Filed: Apr. 23, 2013

(30) Foreign Application Priority Data
Jun. 18, 2012 (CN) 2012102007557

(51) Int. Cl. H05K 7/12

(52) U.S. Cl. CPC H05K 7/12
USPC 248/316.7; 403/330

(57) ABSTRACT

A mounting apparatus is used for mounting a connecter assembly. The connecter assembly includes a retaining board. The mounting apparatus includes a bracket, and a locking member. The locking member is mounted to the bracket. The locking member includes a body, a holding arm extending from the body, and a locking arm extending from the body. The holding arm and the locking arm are spaced from each other. The locking arm is resilient away from the holding arm. A retaining tab protrudes from the locking arm toward the holding arm. The retaining tab blocks the retaining board.

### BACKGROUND

The disclosure generally relates to a mounting apparatus for a connector assembly in a computer.

### Description of Related Art

A plurality of fans is used in most computers for heat dissipation. Each fan is powered through a flexible power cable which is directly connected to a motherboard of a computer from one side of the fan. When replacing or repairing the fan, the flexible power cable of the fan must be pulled out first from the motherboard. During the unplugging process, interference may be created by other cables or electronic components in the computer. There is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a mounting apparatus for retaining two connector assemblies in one embodiment.

FIG. 2 is an isometric view of a locking member of the mounting apparatus of FIG. 1.

FIG. 3 is a partial assembly view of the mounting apparatus of FIG. 1.

FIG. 4 is similar to FIG. 3, but the two locking members are mounted to a bracket.

FIG. 5 is a lateral schematic view of one of connector assemblies and the locking member of FIG. 4, when the connector member engages with the locking member.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

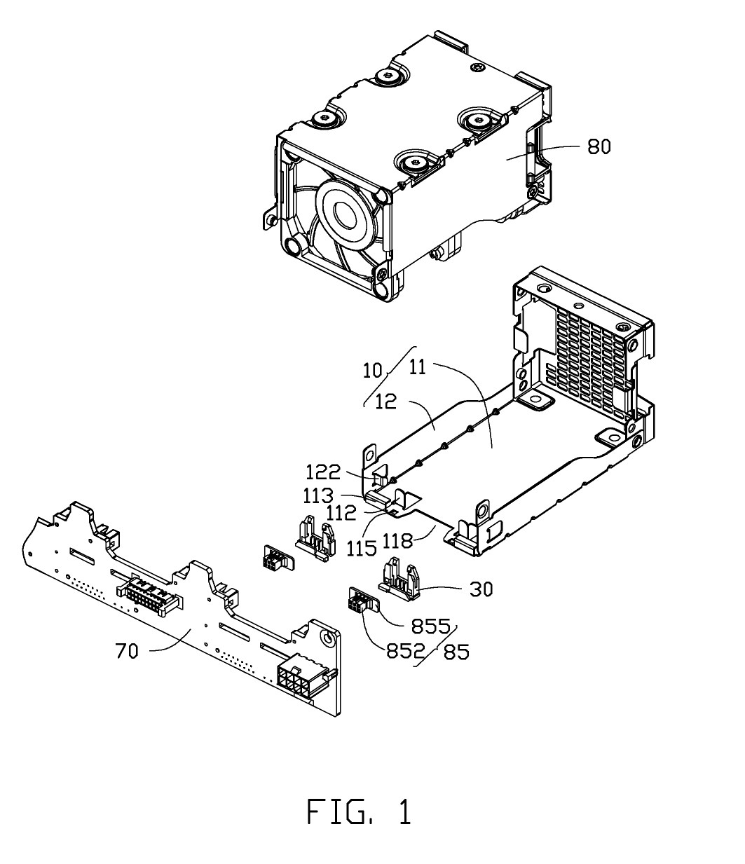

FIG. 1 illustrates one embodiment of a mounting apparatus for retaining a connector assembly 85. The connector assembly 85 can receive power from a rear plate 70 and supply it to a fan assembly 80.

The connector assembly 85 includes a retaining board 855 and a connector 852 located on the retaining board 855.

The mounting apparatus includes a bracket 10 and two locking members 30. The bracket 10 includes a bottom wall 11 and a side wall 12. The bracket 10 can receive and retain the fan assembly 80. Two retaining flanges 113 and two guiding tabs 112 are located on the bottom wall 11 for guiding the locking members 30. Each retaining flange 113 extends from an outer edge of the bottom wall 11. Each retaining flange 113 is substantially L-shaped. An elastic tab 122 is located on each side wall 12 for retaining each locking member 30. Two locking openings 115 are defined in the bottom wall 11. A cutout 118 is defined at the outer edge of the bottom wall 11.

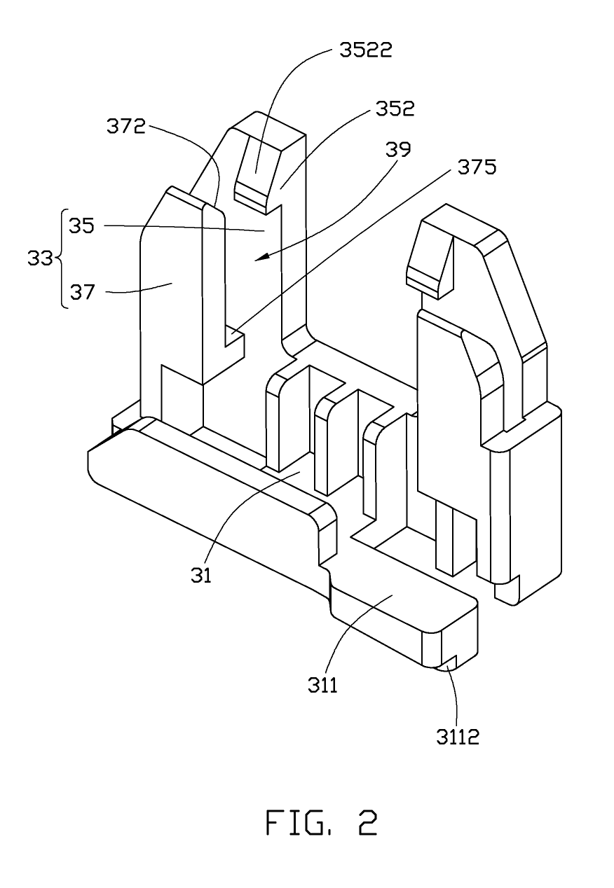

FIG. 2 illustrates one of locking members 30. Each locking member 30 includes a body 31, a cantilever arm 311, and two pairs of arm assemblies 33. Each locking member 30 is substantially U-shaped. The cantilever arm 311 horizontally extends from the body 31. A protrusion 3112 extends from a distal end of the cantilever arm 311. The two pairs of arm assemblies 33 are located on opposite sides of the body 31. Each pair of arm assemblies 33 includes a locking arm 35 and a holding arm 37. The locking arm 35 and the holding arm 37 of one pair of arm assemblies 33 are spaced from each other. The holding arm 37 is substantially parallel to the locking arm 35 at an original state. A carrying portion 375 horizontally extends from the holding arm 37 at a bottom portion of the holding arm 37. A retaining tab 352 protrudes from a top portion of the locking arm 35 toward the holding arm 37. The retaining tab 352 includes a guiding surface 3522. The guiding surface 3522 is slanted down towards the holding arm 37. A slanted abutting surface 372 is defined in a top portion of the holding arm 37. The holding arm 37 is resilient. A retaining space 39 is defined between the locking arms 35 and the holding arms 37.

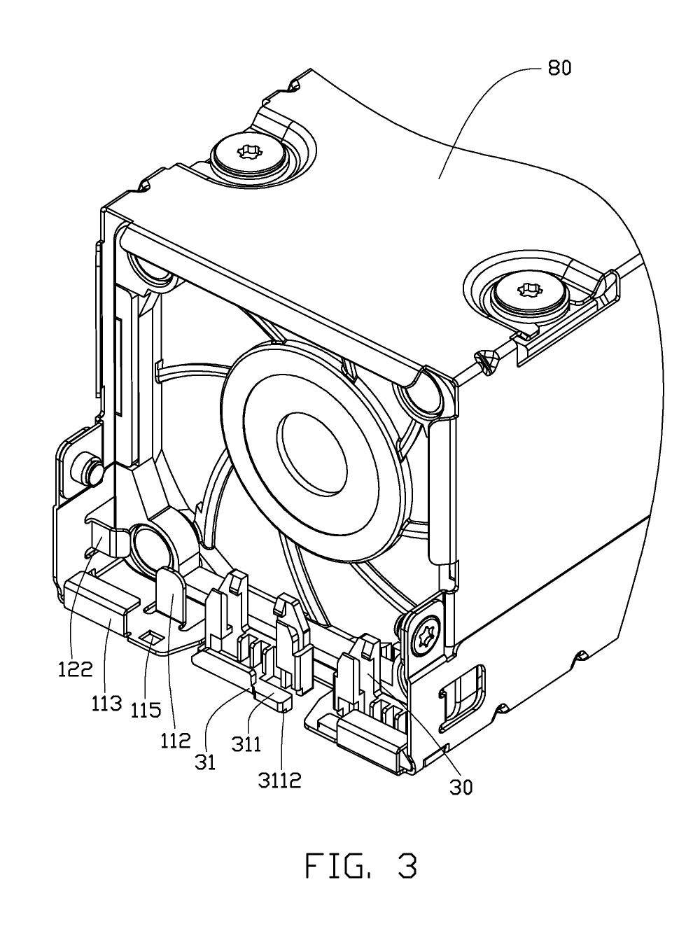

FIG. 3 illustrates a partial assembly view of the fan assembly 80, the bracket 10 and the locking members 30. In assembly, the fan assembly 80 is mounted to the bracket 10. The locking member 30 is located on the cutout 118 of the bracket 10. The locking member 30 is moved sideward. The locking member 30 is guided in by the retaining flange 113 and the guiding tab 112. The protrusion 3112 of the cantilever arm 311 abuts the bottom wall 11, and the cantilever arm 311 lifts up. The locking member 30 abuts the elastic tab 122 urging the elastic tab 122 to deform. The elastic tab 122 deforms back to retain the locking member 30 to the bracket 10. When the protrusion 3112 reaches the locking opening 115, the cantilever arm 311 deforms back. The protrusion 3112 is engaged with the locking opening 115. The locking members 30 are mounted to the bracket 10 on a side of the fan assembly 80.

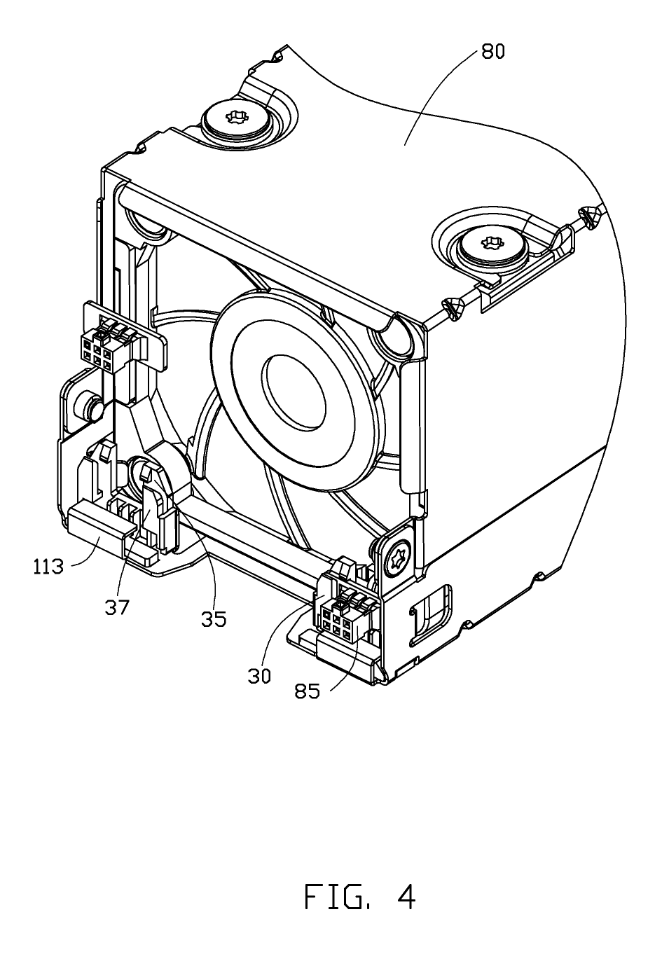

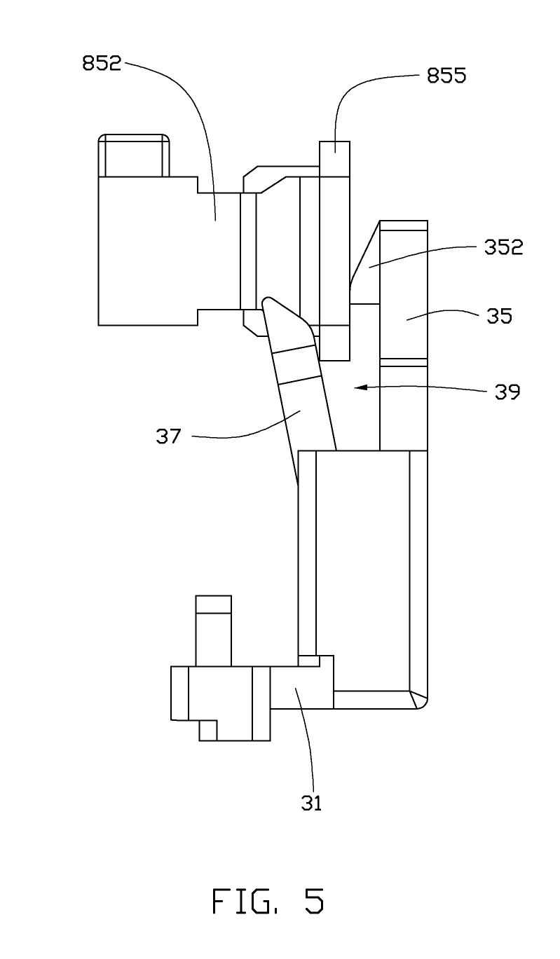

FIG. 4 and FIG. 5 show that the connector assembly 85 is mounted to the rear plate 70. The two connector assemblies 85 are located on top of the two locking members 30. The rear plate 70 with the connecter assemblies 85 are moved down into the retaining space 39. The retaining board 855 of each connector assembly 85 is guided by the guiding surfaces 3522 of the locking arms 35. A bottom portion of the retaining board 855 abuts and deforms the holding arms 37. The holding arms 37 are deformed away from the locking arms 35. When the two retaining boards 855 are totally moved into the retaining space 39, the holding arms 37 are deformed back to the original state. The connecter assemblies 85 are retained in the locking members 30.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A mounting apparatus for a connecter assembly, the connecter assembly comprising a retaining board, the mounting apparatus comprising:
a bracket; and
a locking member mounted to the bracket, the locking member comprising a body, a holding arm extending from the body, and a locking arm extending from the body; and the holding arm and the locking arm being spaced from each other, the locking arm being resilient away form the holding arm, a retaining tab protruding form the locking arm toward the holding arm,
wherein the retaining board is blocked by the retaining tab.

2. The mounting apparatus of claim 1, wherein the locking member further comprises a cantilever arm, a protrusion is located on an end of the cantilever arm, and a locking opening is defined in the bracket for engaging the protrusion.

3. The mounting apparatus of claim 1, wherein the holding arm is substantially parallel to the locking arm.

4. The mounting apparatus of claim 1, wherein a carrying portion extends from the holding arm.

5. The mounting apparatus of claim 1, wherein a height of the locking arm is greater than that of the holding arm.

6. The mounting apparatus of claim 5, wherein the retaining tab comprises a guiding surface, and the guiding surface is slanted towards the holding arm.

7. The mounting apparatus of claim 1, wherein the bracket comprises a bottom wall, and an L-shaped retaining flange and a guiding tab are located on the bottom wall to retain the connecter assembly.

8. The mounting apparatus of claim 7, wherein the bracket further comprises a side wall, and an elastic tab extends from the side wall for engaging with the retaining board.

9. A locking member for retaining a connecter assembly, the connecter assembly comprising a retaining board, the locking member comprising:
a body;
a holding arm extending from the body; and
a locking arm extending from the body, the holding arm and the locking arm being spaced from each other, the locking arm being resilient away form the holding arm, and a retaining tab protruding form the locking arm toward the holding arm,
wherein the retaining board is blocked by the retaining tab.

10. The locking member of claim 9, wherein the locking member further comprises a cantilever arm, and a protrusion is located on an end of the cantilever arm to engage with a bracket.

11. The locking member of claim 9, wherein the holding arm is substantially parallel to the locking arm.

12. The locking member of claim 9, wherein a carrying portion extends from the holding arm.

13. The locking member of claim 9, wherein a height of the locking arm is greater than that of the holding arm.

14. The locking member of claim 13, wherein the retaining tab comprises a guiding surface, the guiding surface is slanted towards the holding arm, and the holding arm is resilient.

15. A locking member for retaining a connecter assembly, the connecter assembly comprising a retaining board, the locking member comprising:
a body; and
two pairs of arm assemblies, each of two pairs of arm assemblies comprising:
a holding arm extending from the body; and
a locking arm extending from the body, the holding arm and the locking arm being spaced from each other, the locking arm being resilient away form the holding arm, a retaining tab protruding form the locking arm toward the holding arm,
wherein the retaining board is blocked by the retaining tabs.

16. The locking member of claim 15, wherein the locking member is substantially U-shaped.

17. The locking member of claim 15, wherein a carrying portion extends from the holding arm.

18. The locking member of claim 15, wherein a height of the locking arm is greater than that of the holding arm.

19. The locking member of claim 15, wherein the retaining tab comprises a guiding surface, and the guiding surface is slanted towards the holding arm, and the holding arm is resilient.
